(19) United States
(12) Patent Application Publication
(10) Pub. No.: US 2026/0111631 A1
(43) Pub. Date: Apr. 23, 2026

(54) MODELING ENERGY CONSUMPTION IN TOOLS

(71) Applicant: GlobalFoundries Dresden Module One Limited Liability Company & Co. KG, Dresden (DE)

(72) Inventors: Peter John, Radebeul (DE); Grit Herrmann, Dresden (DE); Ulf Lederer, Dresden (DE); Stefan Maschke, Dresden (DE); Frank Wagenbreth, Radebeul (DE); Martin Werner, Dresden (DE); Troy Vargason, Clifton Park, NY (US); GOPALA KRISHNA ANNE, KARNATAKA (IN); Ramaguru Balakrishnan, Tamilnadu (IN); Sabha Krishnan Alagarsamy Muthukrishnan, Tamilnadu (IN); Uwe Leucke, Dresden (DE)

(21) Appl. No.: 18/918,876

(22) Filed: Oct. 17, 2024

(51) Int. Cl. G06F 30/27

(52) U.S. Cl. CPC G06F 30/27

(57) ABSTRACT

The present disclosure relates to energy consumption of tools and, more particularly, to modeling energy consumption in semiconductor tools. The method includes: obtain, by a computing device, a state history of a tool over a predetermined period of time; model, by the computing device, the state history of the tool using machine learning to provide a predicted energy usage of the tool; compare, by the computing device, predicted energy usage obtained from the machine learning model to an actual energy usage of the tool; and determine, by the computing device, a deviation between the actual energy usage and the predicted energy usage of the tool to maintain energy consumption efficiency of the tool.

### BACKGROUND

The present disclosure relates to energy consumption of tools and, more particularly, to modeling energy consumption in semiconductor tools.

Integrated circuits are manufactured using a large number of processes using different process tools in a semiconductor facility (e.g., semiconductor fab). The process tools may be, for example, deposition chambers, plasma etching chambers, etc. These process tools require a significant amount of energy. For this reason, it is of great importance for the semiconductor manufacturer to monitor the processes and process tools to maximize energy efficiency.

### SUMMARY

In an aspect of the disclosure, there is a computer-implemented method including: obtain, by a computing device, a parameter of a tool over a predetermined period of time; model, by the computing device, the parameter of the tool using machine learning to provide a predicted energy usage of the tool; compare, by the computing device, predicted energy usage obtained from the machine learning model to an actual energy usage of the tool; and determine, by the computing device, a deviation between the actual energy usage and the predicted energy usage of the tool to maintain energy consumption efficiency of the tool.

In an aspect of the disclosure, there is a computer program product including one or more computer readable storage media having program instructions collectively stored on the one or more computer readable storage media. The program instructions are executable to: accumulate a parameter over a period of interest of a tool, the parameter comprising energy consumption of different operational states over a predetermined period of time; model the parameter of the tool using machine learning to predict energy consumption of the tool over a selected subset of the different operational states; compare the energy usage prediction from the machine learning model to actual energy usage of the tool; and determine a deviation between the actual energy usage and the predicted energy of the tool to maintain energy consumption efficiency of the tool.

In an aspect of the disclosure, there is system including a processor, a computer readable memory, one or more computer readable storage media, and program instructions collectively stored on the one or more computer readable storage media. The program instructions are executable to: accumulate a parameter over a period of interest of a tool, the parameter comprising energy consumption of different operational states over a predetermined period of time; model the parameter of the tool using machine learning to predict energy consumption of the tool over a selected subset of the different operational states; compare the energy usage prediction from the machine learning model to actual energy usage of the tool; and determine a deviation between the actual energy usage and the predicted energy of the tool and to increase energy consumption efficiency of the tool.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 depicts a cloud computing node according to an embodiment of the present disclosure.

FIG. 2 shows a block diagram of an exemplary environment in accordance with aspects of the present disclosure.

FIG. 3 shows a chart of E10 states for an exemplary tool shown in FIG. 2 in accordance with aspects of the present disclosure.

FIG. 4 shows a visualization of energy consumption in accordance with aspects of the present disclosure.

FIGS. 5 and 6 show E10 status of a tool at certain time periods in accordance with aspects of the present disclosure.

FIG. 7 shows a graph of production activities (PRD) in accordance with aspects of the present disclosure.

FIG. 8 shows a graph of development activities (DEV) in accordance with aspects of the present disclosure.

FIG. 9 shows a graph of test activities (TEST) in accordance with aspects of the present disclosure.

FIG. 10 shows heat map plots in accordance with aspects of the present disclosure.

FIGS. 11 and 12 show the application of the model to all data points for a past time period in accordance with aspects of the present disclosure.

FIGS. 13 and 14 show predicted and real measured values in accordance with aspects of the present disclosure.

FIG. 15 shows a use case in accordance with aspects of the present disclosure.

FIG. 16 shows Gantt charts corresponding to a use case in accordance with aspects of the present disclosure.

FIG. 17 shows a flowchart of an exemplary method in accordance with aspects of the present disclosure.

### DETAILED DESCRIPTION

The present disclosure relates to energy consumption of tools and, more particularly, to modeling energy consumption in semiconductor tools, e.g., semiconductor equipment within a semiconductor fab. The tools may be, for example, an etch chamber, deposition chambers, etc. In embodiments, the modeled energy consumption may be based on historical usage over a predetermined time period, e.g., one year time period, for a particular tool during particular operational states, which can be compared to the same tool used in the future for the same time period with different operation states. For example, a multi-linear regression model may be created on a tool level to detect any quantifiable variations of energy consumption with a certain time resolution, e.g., 1 hour resolution, over a certain time period, e.g., one year, in any of six E10 operational states. The modeled energy consumption may be compared to the energy consumption of the same tool during another time period of the same duration, during different E10 operational states. In this way, it is possible to determine whether energy savings were gained using the same tool, compared to prior usages. In embodiments, the model can be used on any production tools that has available E10 cluster states or other standards.

In more specific embodiments, the systems and processes described herein provide a technical solution to a technical problem of determining energy consumption and confirm energy savings in semiconductor tools, regardless of the operational states of the tools as measured during a same time duration but at different time periods, e.g., future usage. The systems and processes include the technical feature of modeling energy consumption of one or more tools over certain E10 operational states. The models can determine or predict deviations from historical chamber (e.g., tool) energy use over different E10 operational states. This problem is an intractable problem using conventional processes as the tool may be used in different operational states with different energy consumption from one time period to another time period.

The technical feature, as described in more detail, can also provide the process engineer with additional information to ensure that the semiconductor tool is running in a most efficient manner for energy efficiency. For example, the technical solution provides a practical application to the technical problem of energy consumption and savings of energy usage in semiconductor tools over time and during different process parameters. Illustratively and described in more detail herein, implementation of the systems and processes described herein will determine the energy consumption of a particular tool and directly correlate he energy consumption to particular parameters of the semiconductor tool over predetermined time periods. This comparison of energy consumption can be fed back to process engineers, which can use the underlying information of the E10 states and time frame to determine which parameters of the tool need to be adjusted to achieve further energy consumption savings.

Accordingly, the underlying information can be used by the process engineers to adjust the semiconductor tool with the same processing parameters (if energy consumption was less than historical energy consumption) or different processes should it be determined that past adjustments did not save energy. Accordingly, implementing the systems and processes herein is a very powerful tool to accurately determine energy consumption of a particular tool, relate it to particular parameters used in the fabrication processes and adjust the semiconductor tools to run most efficiently from an energy consumption perspective.

Accordingly, it is now possible to predict energy consumption for all six operational E10 states of a tool. And it is now possible to accurately predict and check whether energy-saving measures have been successfully implemented in production equipment, e.g., semiconductor tools, by a comparison with previous energy consumption (baseline comparison), regardless of whether different operational states were used by the tool over a same duration of time. For example, the machine learning model can be used as the baseline model for each tool which allows the comparison in all six basic operational states of the E10 standard, which was not previously possible. In addition, the models and analysis can be provided in a greater granularity as described herein, e.g., detect deviations from the baseline (e.g., previous year) and to quantify the deviations from a per hour basis, thereby providing a more accurate assessment of energy consumption.

As should be recognized by one of skill in the art, E10 are operational standards that provide baseline equipment performance information utilized for capacity analysis and constraint analysis, in addition to baseline data for a suite of higher level performance metrics including Cost of Ownership for semiconductor equipment. The E10 standards define six operational states of a tool, including:
(1) productive state (PRD): the equipment is processing material, such as etching silicon, depositing a substrate, or measuring dimensions;
(2) standby state (SBY): the equipment is available for processing material but is not currently doing so;
(3) engineering state (ENG): the process tool is available but engineering experiments, tests, or other activities that produce non-productive or non-sellable results;
(4) scheduled downtown state (SDT): the equipment is not in production and is taken offline for a scheduled period e.g., scheduled maintenance or recalibration, production tests, preventative maintenance (PM), changing consumables, setup of process change, etc.;
(5) unscheduled down time state (UDT): the equipment is not in production and is taken offline for an unscheduled period e.g., repair, maintenance or other period during which the process tool is not in a condition to perform its intended function due to unplanned downtime events; and
(6) unscheduled state: the period of non-scheduled time during which the process tool is not scheduled to be utilized in production, e.g., periods including off-line training, unworked shifts, weekends, holidays etc.

As should also be understood by those of skill in the art, operation time may be divided into uptime and downtime. The uptime may be divided into engineering time and manufacturing time. The manufacturing time includes a productive time and a standby time. The productive time, standby time and engineering time correspond to states 1-3; whereas downtime may be divided into scheduled downtime and unscheduled downtime corresponding to states 4 and 5.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium or media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time. In embodiments, the models implemented on the cloud are scalable.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

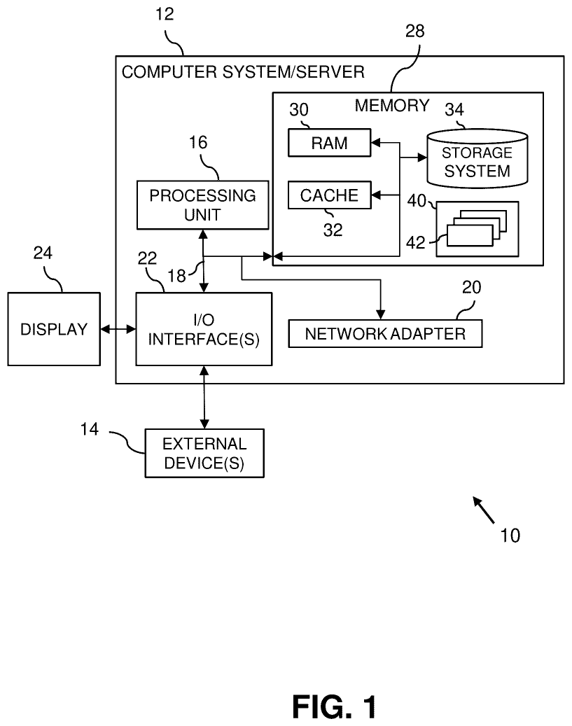

Referring now to FIG. 1, a schematic of an example of a cloud computing node is shown. Cloud computing node 10 is only one example of a suitable cloud computing node and is not intended to suggest any limitation as to the scope of use or functionality of embodiments of the invention described herein. Regardless, cloud computing node 10 is capable of being implemented and/or performing any of the functionality set forth hereinabove.

In cloud computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

As should be understood by those of skill in the art, a cloud computing environment includes one or more cloud computing nodes 10 with which local computing devices used by cloud consumers. Nodes 10 may communicate with one another. They may be grouped (not shown) physically or virtually, in one or more networks, such as Private, Community, Public, or Hybrid clouds as described hereinabove, or a combination thereof. This allows cloud computing environment to offer infrastructure, platforms and/or software as services for which a cloud consumer does not need to maintain resources on a local computing device. The model described herein may be scalable with the cloud computing environment.

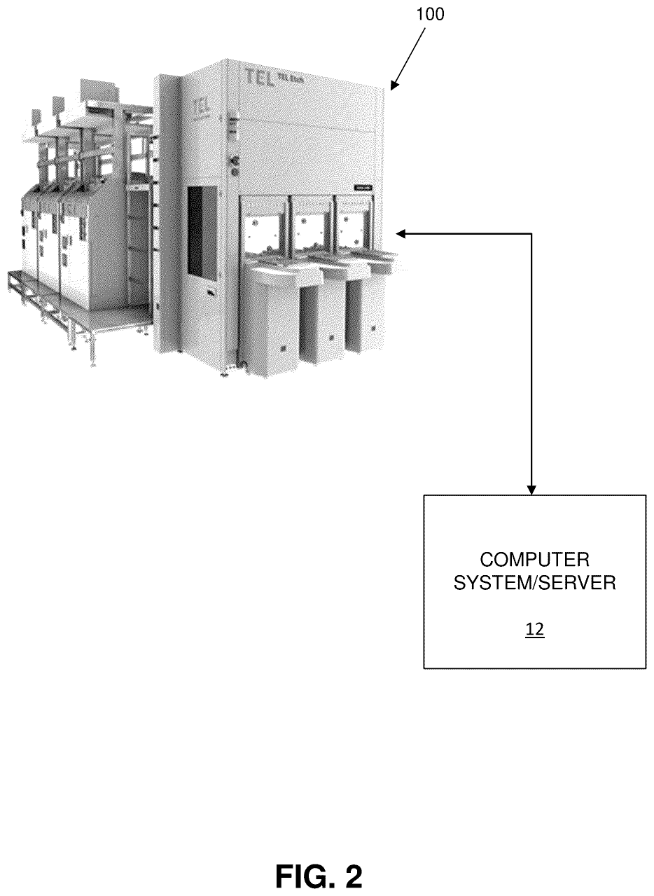

FIG. 2 shows a block diagram of an exemplary environment in accordance with aspects of the invention. In embodiments, the environment includes at least one processing tool 100 in communication with the computer system/server 12 or FIG. 1. The processing tool 100 may be any semiconductor production tool such as a plasma etch system with multiple chambers, etc. As should be understood by those of skill in the art, power consumption increases during the etching process compared to a standby mode and, accordingly, the duration and number of processed wafers of the etching process are decisive for the power consumption, amongst other factors taken into consideration during the processes described herein. Also, it should be understood by those of skill in the art that process tools are very complex with different functional modules. These functional modules may be referred to as cluster tools which can operate in a parallel and/or sequential manner. Typically, performance of a multi-path cluster tool is derived from the performance of the individual process paths as the E10 standard does not allow handling multi-path cluster tools at an overall level and, instead, are applied to the individual tool entities.

In embodiments, the computer system/server 12 may comprise different modules to perform the functions described herein, including, for example, accumulating chamber state history over the period of interest, modeling the chamber history using a linear regression analysis (e.g., modeling) to provide a prediction of energy usage, comparing energy usage prediction from the model to an actual energy usage, determining significant deviation between actual and predicted energy over the period of time (which may different operational states) and notifying a user of such deviation, and determining the E10 cluster states which correlate to the energy consumption entering the chamber state history into the machine learning model. In embodiments, the E10 cluster states may be weighted using, for example, weighted entity states as is known in the art (for building models from relevant variables as described herein).

In the processes described herein, for example, the duration of each processing step is tracked and retrieved for each individual wafer. During the processing of a wafer, the system is in a productive state; whereas if no wafers are to be processed, the system is in standby mode or in a down state in accordance with the six tool states of the E10 standards. In case of multi-chamber-tools, an Equipment Interface (EI) reads the status of the individual chamber states and a Data Warehouse algorithm calculates the individual E10 states for the cluster (e.g., equal to the aggregation from chamber to tool level). In embodiments, the EI provides the raw data to the Data Warehouse algorithm which, in turn, calculates the E10 cluster states. The cluster states can then be used for the correlation of the energy consumption. In embodiments, a Data Warehouse algorithm may be used to calculate the E10 cluster states of the semiconductor tools as is known in the art. For example, a known Data Warehouse algorithm used to calculate cluster states may be found in U.S. Pat. No. 7,546,177, which is incorporated by reference in its entirety herein. In a particular, non-limiting example, the tool states of a Production Tool includes:
PM1: Standby (E10-Standby) for the whole 8 h shift;
PM2: Productive (E10-Productive), switched to Standby after 3 h;
PM3: Maintenance (E10-Scheduled Downtime) for the whole 8 h shift;
PM4: Productive with a short break;
PM5: Productive, switched to Standby after 3 h; and
PM6: Standby, for the whole 8 h shift.

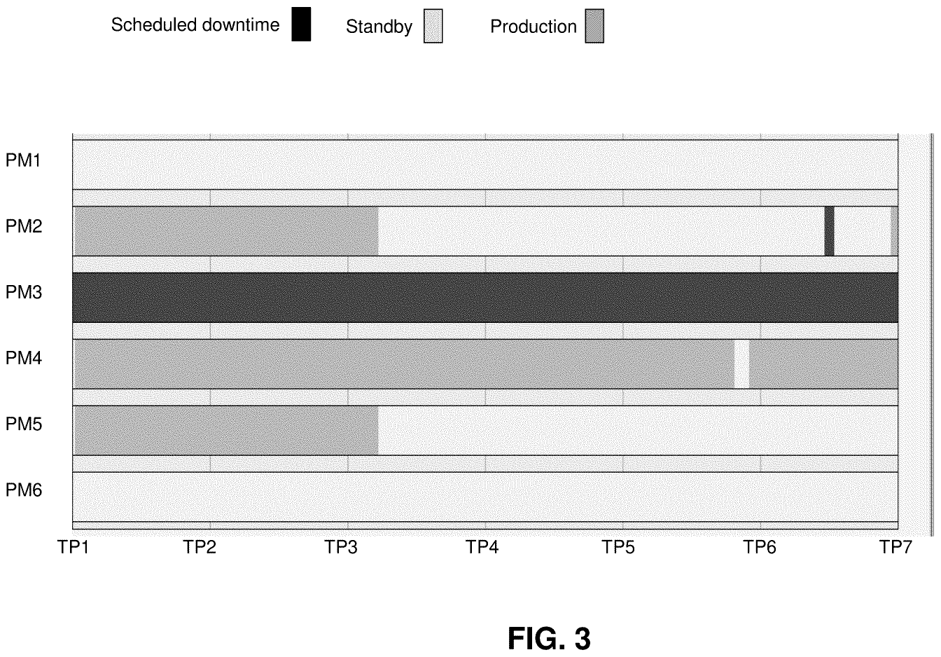

FIG. 3 shows a chart of E10 states for an exemplary tool 100 shown in FIG. 2. The chart represents six chambers during an 8 hour shift as shown in the x-axis as TP1-TP7. The chart specifically shows the above noted six operational states of the tool as graphed on the y-axis and as shown in the legend, e.g., standby mode (SBY), production mode (PRD) and scheduled downtime mode (SDT). In this graphical representation, the corresponding E10 cluster states (i.e., the overall E10 States) in the 1^{st} hour of the shift include:

$$E10\_PRD = 50 \% ( 3 / 6 chambers up and running ) ;$$

$$E10\_SBY = 33 \% ( 2 / 6 chambers waiting ) ; and$$

$$E10\_SDT = 17 \% ( 1 / 6 chamber down ) .$$

It should be recognized that the six operational states will always sum to 100%. Accordingly, if five states are known, the sixth operational state can be calculated from the sum of the other five operational states, e.g., 100%−(state 1+state 2+state 3+state 4+state 5)=state 6. In addition to the number of wafers (e.g., activities), other characteristics can be queried in the data warehouse, e.g., storage system of FIG. 1 (which saves historical tool data). These other characteristics could also have an influence on power consumption. These additional queries include, for example, production, development and test activities, referring to the number of wafers (e.g., wafers that are being sold or used to qualify a production tool or development wafers) of these types that were processed per hour.

It should also be understood that the above calculations can vary, providing different results. For example, the above calculations can be provided by using the Data warehouse algorithm as described herein. Also, the calculations (e.g., cluster calculations) may consider different throughputs of different chambers. So, for example, a higher throughput of a tool can provide a different percentage for the production or other E10 state, e.g., E10_PRD=51% due to a higher throughput of PM4. In addition, it should be understood that the calculations can be provided during any time period, e.g., TP2-TP3, etc.

The following discussion shows an exemplary method in accordance with aspects of the present invention. The steps provided below are indicative of an exemplary flow of the processes described by the present disclosure. The different steps of the method may be carried out in the environment of FIG. 1 and, for example, can be carried out on the computing environment as either a hardware product and/or in a computer program product.

In an embodiment of the processes described herein, the consumed energy of a tool 100 may be recorded and stored in a predetermined cycle, e.g., 5 second cycle, over a year time period. A power analyzer on the tool 100 shown in FIG. 2 can record the sum of the energy consumption of the different process chambers. The power analyzer can measure the current and voltage of the production tool over a known time period to provide energy consumption. Advantageously, the processes described herein can measure the entire production tool and not each process chamber level of the production tool. This information can be exported by management software as aggregated measured values as is known in the art. For example, GridVis monitoring software allows the export of aggregated measured values as provided by the power analyzer tool. (GridVis is a registered trademark of Janitza electronics GmbH.) As is understood by those of skill in the art, GridVis monitoring software provides energy management as one of many different functions. In embodiments, the historical data and current energy use data can be stored by the hour or other predetermined time period. Also, as an example, a data pipeline may be set up to pull data from the from the on premise system e.g., GridVis, to an external cloud.

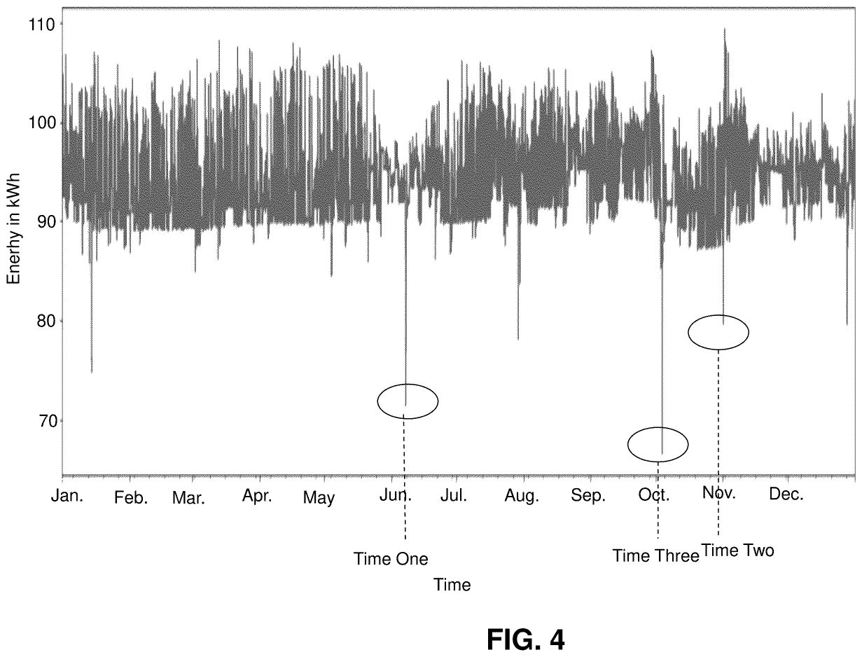

In the example described herein, the data files can be uploaded into individual data frames and sorted by date. From the visualization of the power consumption as shown in FIG. 4, for example, it is seen that the tool under observation, e.g., tool 100, consumes about 90 kWh per h in the base load with peaks up to 110 kWh per h.

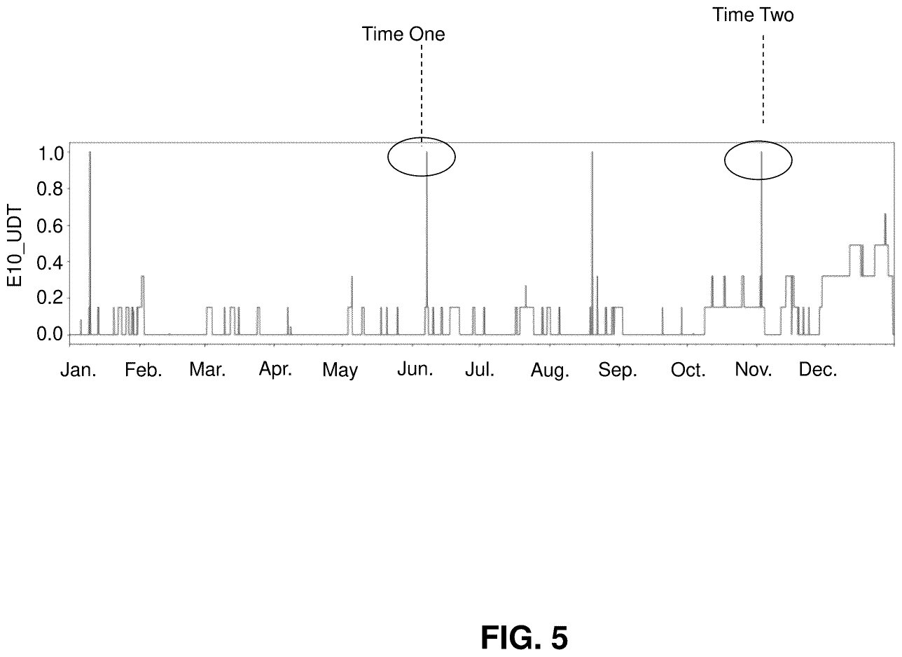

In FIG. 4, the x-axis is time (e.g., per month in hours) and the y-axis is energy in kWh. In this representation, the E10 state values range between 0 and 1.0 and the visualization of the energy consumption shows anomalies such as consumption drops, e.g., approx. 70 kWh at time period one and approximately 80 kWh at time period two. This coincides with the E10 status UDT=1.0 at the time period one and time period two as shown in FIG. 5. The x-axis in FIG. 5 is in time, e.g., per month in hours. Another anomaly is the low energy consumption (<70 kWh) at the time three of FIG. 4, which coincides with the E10 status of non-scheduled time (NST), which has the value “1.0” only at this time as shown in FIG. 6 (with the x-axis showing per month in hours). It should be understood that the state E10_NST is used when tools have to be shut down unexpectedly (e.g. due to a fab shutdown).

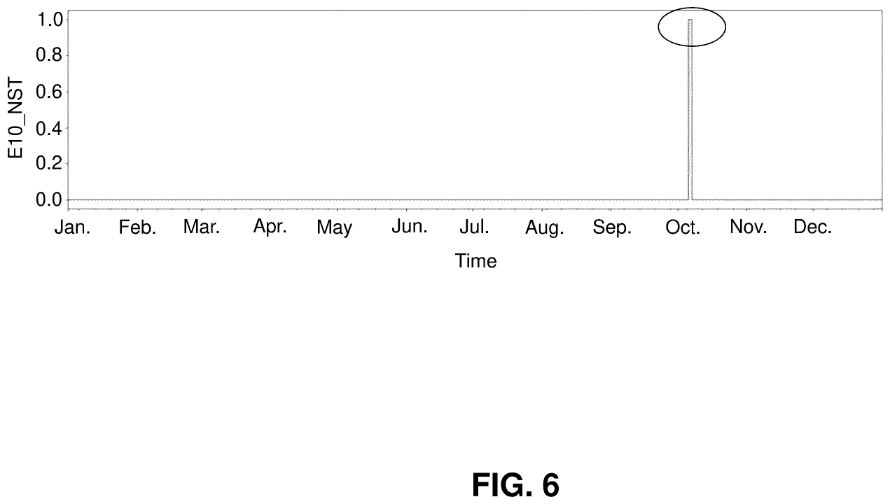

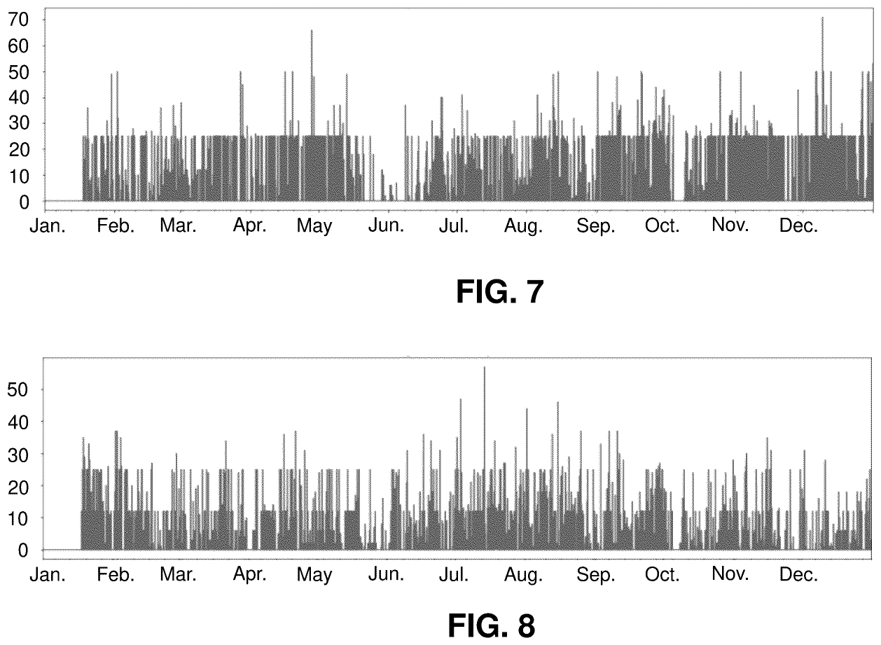

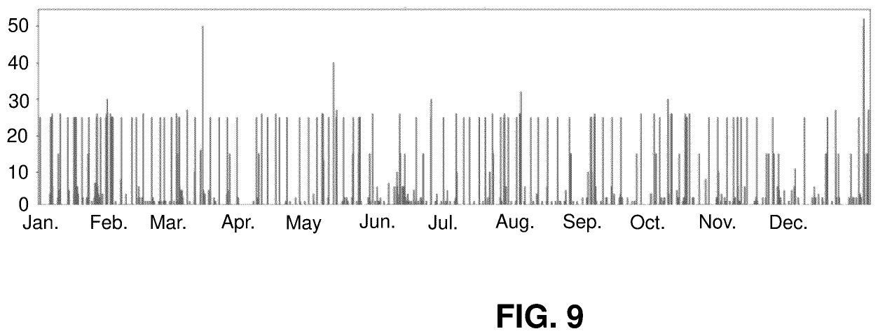

FIG. 7 shows a graph of production activities (PRD), FIG. 8 shows a graph of development activities (DEV) and FIG. 9 shows a graph of test activities (TEST). In each of these graphs, the x-axis is representative of time in months and the y-axis is representative of energy consumption. It should be recognized that any lost data may be dropped for correlation purposes. In embodiments, the data frames (Energy, E10 States and Activities) can be merged allowing further investigation prior to model building.

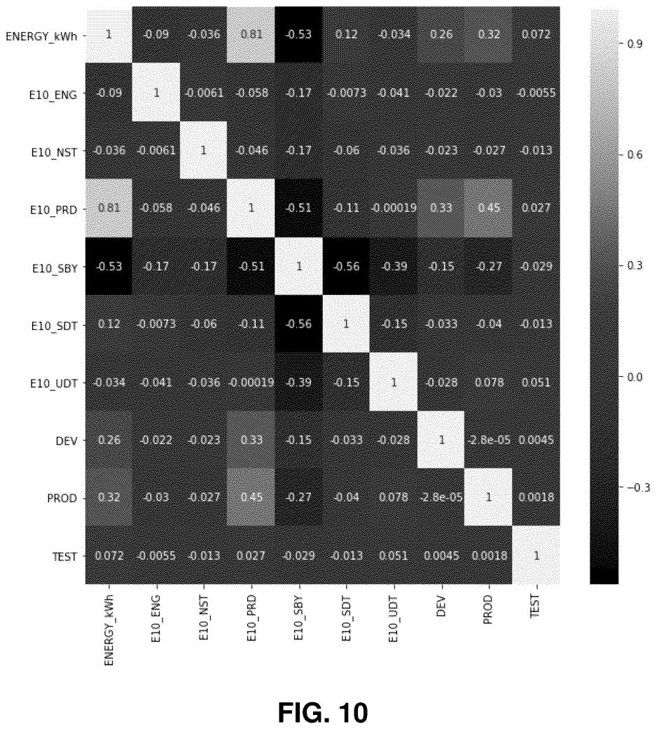

FIG. 10 shows heat map plots in accordance with aspects of the present disclosure. As shown, the heat map in FIG. 10 plots pairwise the correlation of the ten model parameters using a standard correlation coefficient. As has been discussed, the ten model parameters include: engineering (ENG), NST, PRD, SBY, SDT, UDT, DEV, PROD, and TEST. In embodiments, for example, DEV, PROD and TEST may be removed as predictors, or any other combinations of predictors may be used in the present system and processes which can be plotted as a different heat map similar to that which is described in FIG. 10. So, for example, a heat map may be used that shows engineering ENG, NST, PRD, SBY, SDT and UDT.

In embodiments, the standard correlation coefficient may be a Pearson correlation coefficient. As should be understood by those of skill in the art, the Pearson correlation coefficient (r) is a way of measuring a linear correlation. It should further be understood that in implementing the aspects of the present disclosure, R² will be used as a statistical measure of how close the data are to the fitted regression line. As should further be understood by those of skill in the art, the coefficient is a number between −1 and 1 that measures the strength and direction of the relationship between two variables, with 0 indicating no linear correlation between two variables, −1 indicating a perfectly negative linear correlation between two variables and +1 indicating a perfectly positive linear correlation between two variables. The more variance that is accounted for by the regression model, the closer the data points will fall to the fitted regression line. Theoretically, for example, if a model could explain 100% of the variance, the fitted values would always equal the observed values and, therefore, all the data points would fall on the fitted regression line.

As shown in the graph of FIG. 10, the further away the correlation coefficient is from zero (0), the stronger the relationship between the two variables. The highest and lowest coefficients are as follows:
+0.81 @ENERGY_kWh/E10_PRD: almost perfectly positive linear correlation; and
−0.53 @ENERGY_kWh/E10_SBY: strong negative linear correlation.

The coefficients for the pairs ENERGY_kWh/DEV (0.26) and ENERGY_kWh/PROD (0.32) are also comparatively high. Clearly visible is the correlation between DEV and PROD to E10_PRD (0.33/0.45). This would exclude a simultaneous use of E10_PRD and DEV/PROD as predictors. It should be understood by those of skill in the art that the predictors can be any of the six E10 operational states best suited for the statistical model by calculating the coefficient of determination (R²) value for all variants.

In the example, there is a strong correlation between ENERGY and the E10 state E10_PRD. For example, the energy consumption increases with increasing values for E10_PRD. E10_PRD is equal to zero means that at least one other E10 state has a value>0, e.g. E10_NST=1. On the other hand, a negative linear correlation appears between ENERGY and E10_SBY; that is, the more the chambers are in the E10_SBY and thus the E10_SBY cluster state approaches 1.0 (i.e. all chambers in E10_SBY), the less energy is consumed. Because of this analysis, the two E10 operational states E10_PRD and E10_SBY are the only predictors left: the PROD and DEV activities are dependent on E10_PRD and the Pearson Coefficient of the pair ENERGY/TEST activities is close to zero (Pearson Coefficient=0.072). Since the PROD/DEV/TEST activities are not needed for the modeling, the original data frame with 8784 rows (e.g., 366 days*24 hours/day=8784) may be used for modeling. Also, as evaluating for electricity, the relevant variable, e.g., E10 state E10_PRD, is strongly correlated to the consumption of electricity. The correlation is mathematically confirmed using the low Pearson coefficients with the assumption of a strong positive correlation between the dependent variable (Electricity) and the independent variable, E10 state E10_PRD. This relevant independent variable is then used to build the model, which models predicted energy usage.

As to the modeling step, the data can be modeled using a linear regression analysis. The model is capable of analyzing the six E10 operational states to identify in which state more or less energy was consumed vs. a baseline (e.g., historical energy consumption). Also, in embodiments, the model is capable of providing a greater granularity compared to conventional processes. For example, as described herein, it is possible to provide a granularity of 1 hour or less resolution. For clarity, the charts shown in at least shown in FIGS. 4-9 and 11-14 are labeled in monthly intervals in order to visualize longer time periods by having a granularity of 1 hour. In embodiments, the six E10 operational states may be weighted as is known in the art. For example, the weightings for the E10 cluster states may be calculated according to the teachings of U.S. Pat. No. 7,546,177 to provide a highly efficient technique for the measurement and monitoring of cluster tool characteristics. (It should also be noted that weightings (e.g., coefficients) can be applied to the E10 predictors by the linear regression model as described herein.)

The predictors and target variables (e.g., relevant independent variables correlated to energy consumption or efficiency) are numerical data with a linear relationship, in this example, between predictors E10_PROD/E10_SBY and the target. For model building, the columns with the two predictors E10_PRD and E10_SBY may be split in a ratio of 80% for training data and 20% for testing data using the function “train_test_split” from a library “sklearn.model_selection” (i.e., 7027 resp. 1757 rows, 8784 row in total); although other values are also contemplated herein. The selection of data points may be random, with the random state=100 in this example. The modeling can be provided by a linear regression model in Python as shown in the below code.

| | |
|---|---|
| In [50]: | #importing required module to build the model |
| | from sklearn.linear_model import LinearRegression |
| | #building the model |
| | model = LinearRegression( ) |
| | model.fit(x_train,y_train) |
| | prediction=model.predict(x_test) |
| In [51]: | train_score=model.score(x_train,y_train) |
| | test_score =model.score(x_test,y_test) |
| | print(‘Train Score (R-Squared): ’,train_score) |
| | print(‘Test Score (R-Squared): ’,test_score) |
| | Train Score (R-Squared): 0.6776067829329304 |
| | Test Score (R-Squared): 0.698836250004516 |
| In [52]: | # Fetching intercept (b0) and coefficients (b1 and b2) |
| | print(“Intercept:”, model.intercept_) |
| | print(“Coefficients:”,model.coef_) |
| | Intercept: 93.5254727618225 |
| | Coefficients: [18.87630311 −2.47482507] |

The intercept and the two coefficients explain the model: (i) the first coefficient (+18.88) describes the increase of kWh when E10_PRD>0 and (ii) the second coefficient (−2.47) describes the decrease of kWh when E10_SBY>0. If, for example, the tool is in 100% in standby for 1 hour, the energy consumption is 93.53 kWh-2.47 kWh=91.05 kWh.

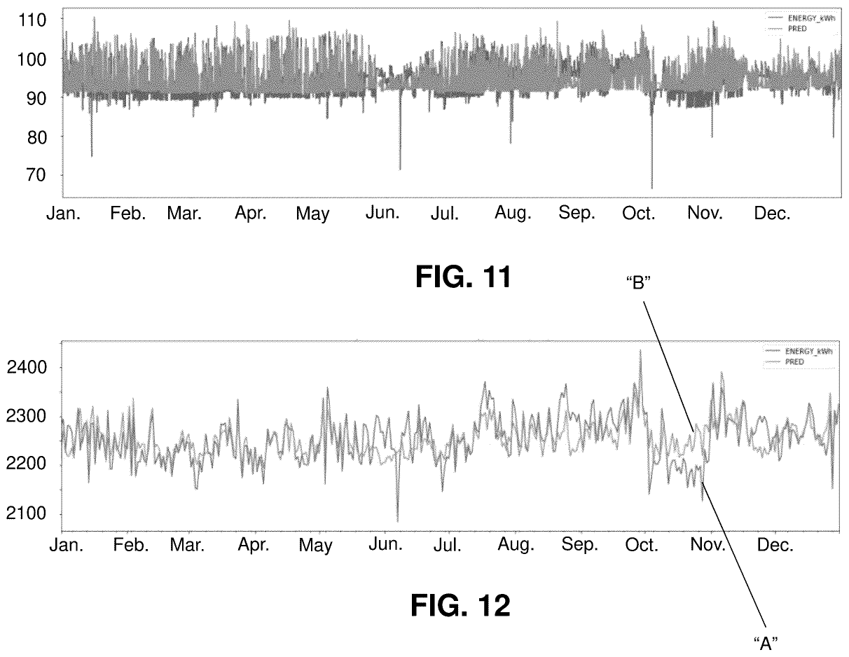

FIGS. 11 and 12 show the application of the model to all data points for a past time period, e.g., year 2020. In FIGS. 11 and 12, the x-axis is time and the y-axis is energy (kWh). More specifically, the time period of FIG. 11 is in hours (labeled by month); whereas the time period of FIG. 12 is in days (labeled by month). In FIG. 11, the darker lines are real measured values and the lighter lines are predicted values. In FIG. 12, the real measured values are shown as line “A” and the predicted values are shown as line “B”. The prediction should not fall below 91.05 kWh per hour, in particular, the consumption drops are not predicted. Comparison of these lines shows whether energy consumption is higher or lower than anticipated/desired.

In this example the behavior was expected because most of the drops correlate with the E10 states E10_UDT and E10_NST, as shown in FIGS. 5 and 6. These two E10 states were not considered in the modeling because of their low Pearson coefficients (refer to FIG. 10). As noted herein, when using linear regression analysis, the determination of Pearson coefficients is helpful to find the correct predictors. Also helpful in evaluating the model are the regression coefficients (b0, b1, and b2), as they clearly describe the model.

In the modeling, an assumption of the regression may be to check after fitting the model, if residuals follow a normal Gaussian distribution. This can visually be verified by using a Q-Q plot as is known in the art.

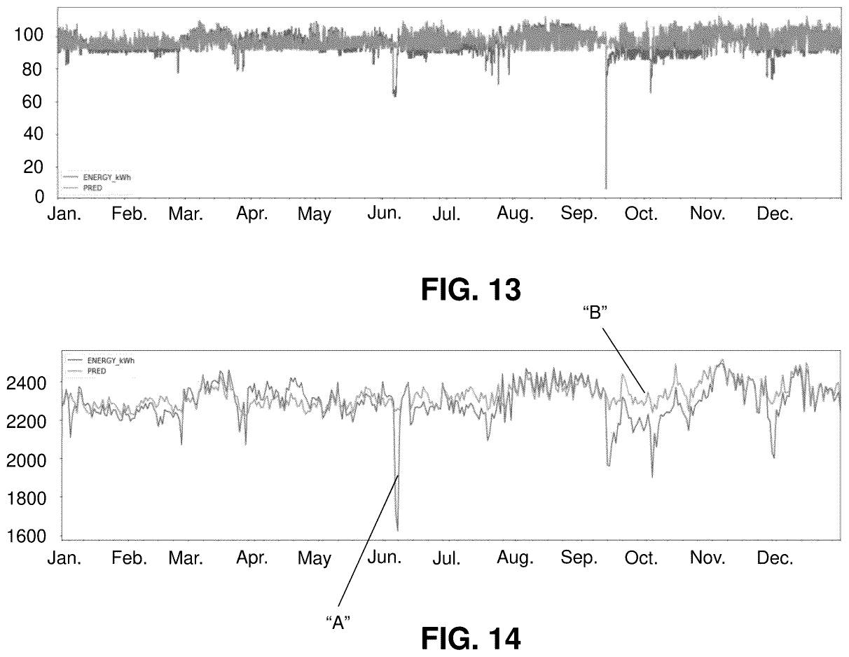

The model implementation can accurately and reliably predict future consumption. To check this, the two cluster E10 operational states E10_PRD and E10_SBY may be loaded into the model and compared with current values. FIGS. 13 and 14, for example, show the predicted and real measured values. In FIGS. 13 and 14, the x-axis is time and the y-axis is energy (kWh). More specifically, the time period of FIG. 13 is in hours, labeled by month; whereas the time period of FIG. 14 is in days, labeled by month In FIG. 13, the darker lines are real measured values and the lighter lines are predicted values. In FIG. 14, the real measured values are shown as line “A” and the predicted values are shown as line “B”.

Accordingly, in the comparison stage, the actual vs. predicted energy consumption can be compared, wherein if the prediction for the subsequent time period is higher than the real measured consumption, the tool has been determined to consume less energy. This reduced energy consumption may be due to heated elements being at different temperatures, e.g., 90° C. in 2020 vs. 60° C. in 2021.

In utilizing the processes described herein, it is now possible to predict energy consumption at production tools using machine learning techniques. This method can be used for any number of tools in a semiconductor fab and is particularly useful for tools with high-energy consumption. These processes will also permit semiconductor fabs to continuously optimize their energy consumption. Also, in the examples provided, the model was built using real measured energy data in 2020 during utilization of a particular tool to predict subsequent energy consumption, e.g., year 2021, etc.; however, this model can use real measured energy data in any time period and predict energy consumption for any subsequent time period. In the comparison stage, the actual vs. predicted energy consumption can be compared, wherein if the prediction for the subsequent time period is higher than the real measured consumption, the tool has been determined to consume less energy. This reduced energy consumption may be due to heated elements being at different temperatures, e.g., 90° C. in 2020 vs. 60° C. in 2021; although other temperatures may be contemplated herein.

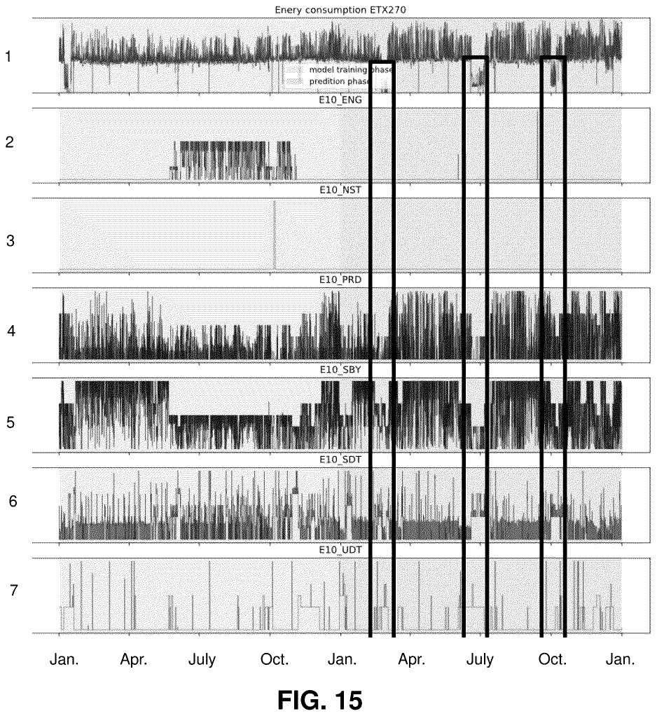

FIG. 15 shows a use case in accordance with aspects of the present disclosure. The top chart labeled 1 shows the energy consumption through 2020 and 2021 per hour and the charts below show the corresponding E10 operational states. For example, the charts labeled 2-7, from top to bottom (below the topmost energy consumption chart) include the following states: 2. engineering, 3. non-scheduled time, 4. productive, 5. standby, 6. scheduled down time and 7. unscheduled downtime. The x-axis is time (e.g., plotted by hour, labeled by month) and the y-axis shows energy ranging from 0 to 100 kWh. In embodiments, the model was trained with historical data from 2020 (lighter shaded background on the left side). In 2020, there were downtimes (i.e., SDT/UDT) with minimal impact on power consumption as shown in the top chart. In 2021, however, the energy consumption dropped significantly during the three highlighted time periods shown in the boxes, i.e., the system behaved differently compared to the previous year.

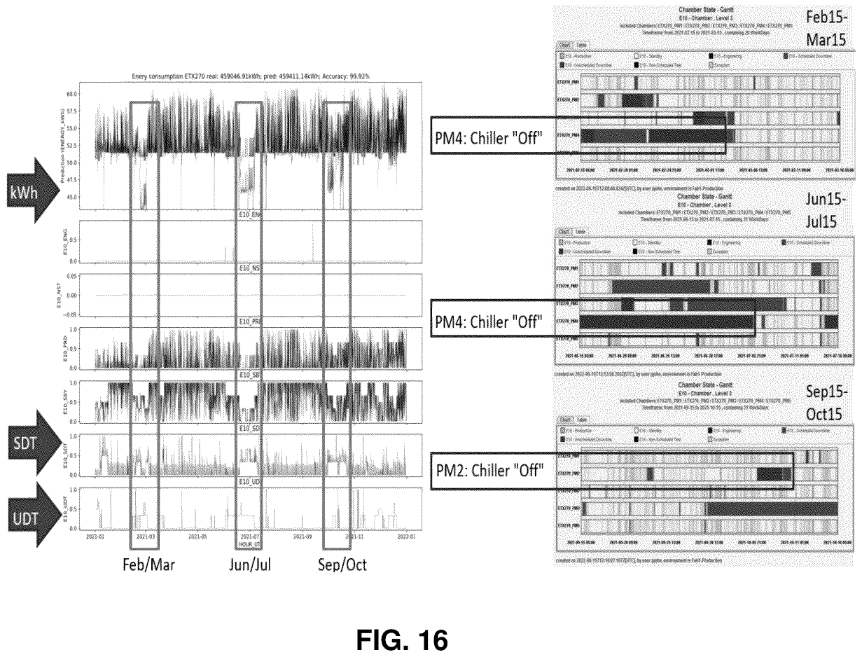

In FIG. 16, Gantt charts are shown corresponding to a use case in accordance with aspects of the present disclosure. The use case may be similar to that shown in FIG. 15. In this representation, the top chart of FIG. 16 shows the energy consumption (actual values as the lighter lines and predicted values as the darker lines) through 2021. As should be understood by those of skill in the art, a Gantt chart may be used in project management as a way of showing activities (tasks or events) displayed against time.

The Gantt charts at the right of FIG. 16 show that chambers PM4 and PM2 have been shut down (SDT and UDT) during certain periods. In contrast to 2020, in 2021 the chambers PM4 and PM2 were disconnected from the grid. In the highlighted portions, e.g., in the boxes corresponding to the charts on the left hand side, the actual energy consumption in the top graph is below the modeled energy consumption, e.g., below the baseline of 2020. This shows the deviations in 2021 compared to 2020 are possible.

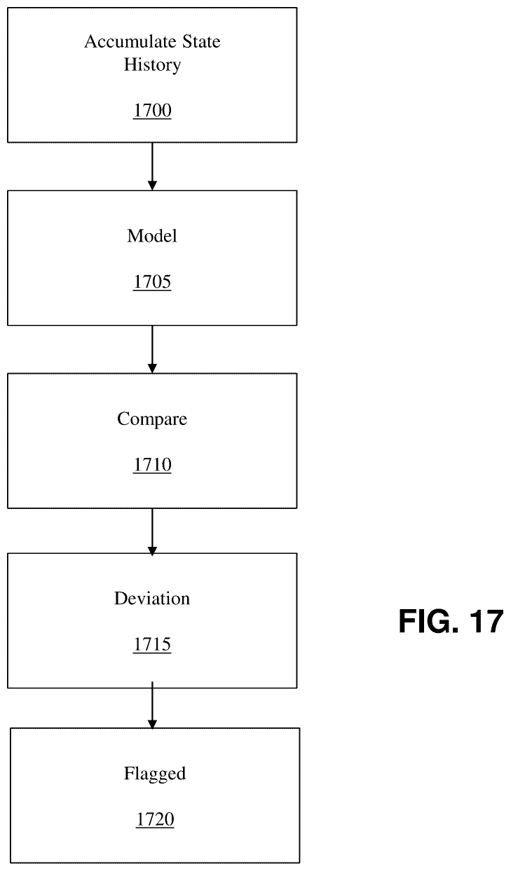

FIG. 17 shows a flowchart of an exemplary method in accordance with aspects of the present disclosure. Steps of the method may be carried out in the environment of FIGS. 1 and 2. At step 1700, the processes accumulate (e.g., obtain) chamber (e.g., tool) state history over a period of interest, including energy use over the period during in any and all of its six operational E10 states. At step 1705, the processes model the state history of the tool using machine learning (history-based). Preferably, the machine learning is based on a regression analysis. As noted herein, the regression analysis is a set of statistical methods used for the estimation of relationships between a dependent variable and one or more independent variables utilized to assess the strength of the relationship between variables and for modeling the future relationship between them. At step 1710, the processes compare energy usage prediction from the machine learning model to actual energy usage of the tool with different operational E10 states over a same duration of time over another time period. At step 1715, the deviations between the actual and predicted values are calculated, and at step 1720, the processes will flag areas of significant deviation to help determine whether E10 cluster states correlate to the required or desired energy consumption.

In embodiments, a service provider could offer to perform the processes described herein. In this case, the service provider can create, maintain, deploy, support, etc., the computer infrastructure that performs the process steps of the invention for one or more customers. These customers may be, for example, any business that uses technology. In return, the service provider can receive payment from the customer(s) under a subscription and/or fee agreement and/or the service provider can receive payment from the sale of advertising content to one or more third parties.

In still additional embodiments, the invention provides a computer-implemented method, via a network. In this case, a computer infrastructure, such as computer system/server 12 (FIG. 1), can be provided and one or more systems for performing the processes of the invention can be obtained (e.g., created, purchased, used, modified, etc.) and deployed to the computer infrastructure. To this extent, the deployment of a system can comprise one or more of: (1) installing program code on a computing device, such as computer system/server 12 (as shown in FIG. 1), from a computer-readable medium; (2) adding one or more computing devices to the computer infrastructure; and (3) incorporating and/or modifying one or more existing systems of the computer infrastructure to enable the computer infrastructure to perform the processes of the invention.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
obtain, by a computing device, a parameter of a tool over a predetermined period of time;
model, by the computing device, the parameter of the tool using machine learning to provide a predicted energy usage of the tool;
compare, by the computing device, predicted energy usage obtained from the machine learning model to an actual energy usage of the tool; and
determine, by the computing device, a deviation between the actual energy usage and the predicted energy usage of the tool to maintain energy consumption efficiency of the tool.

2. The method of claim 1, wherein the model uses an independent relevant variable that relates to energy consumption and is further used to adjust parameters of the tool to maintain or increase energy consumption efficiency of the tool over time.

3. The method of claim 1, wherein the parameter comprises energy consumption and the model further makes use of a state history of the tool, which comprises a history and the energy usage of the tool over a selected subset of one or more operational states of the tool.

4. The method of claim 3, wherein the one or more operational states comprise at least one of: productive state (PRD); standby state (SBY); engineering state (ENG); scheduled downtown state (SDT); unscheduled down time state (UDT); and non-scheduled state (NST).

5. The method of claim 3, wherein the operational states are weighted.

6. The method of claim 3, wherein the state history includes energy consumption over the predetermined period of time during one or more operational states of the tool.

7. The method of claim 1, wherein the machine learning is based on a regression analysis.

8. The method of claim 7, wherein the regression analysis comprises a set of statistical methods used for estimation of relationships between a dependent variable and one or more independent variables of the tool.

9. The method of claim 8, wherein the one or more independent variables comprises determining which of the independent variables of the tool has a strong correlation to energy consumption and using these correlated independent variables in the modeling.

10. The method of claim 1, wherein the comparing of the predicted energy usage to the actual energy usage of the tool is for different operational states of the tool over a same duration of time.

11. The method of claim 1, wherein the modeling step analyzes operational states to identify which operational state uses more or less energy versus a baseline and provides granularity of the energy consumption of 1 hour or less resolution.

12. The method of claim 11, wherein the modeling step uses selected target variables which are numerical data comprising a strong linear relationship with the operational states.

13. The method of claim 1, wherein the modeling comprises training data and test data split from predictors that are relevant to energy consumption of the tool.

14. A computer program product comprising one or more computer readable storage media having program instructions collectively stored on the one or more computer readable storage media, the program instructions executable to:
accumulate a parameter over a period of interest of a tool, the parameter comprising energy consumption of different operational states over a predetermined period of time;
model the parameter of the tool using machine learning to predict energy consumption of the tool over a selected subset of the different operational states;
compare the energy usage prediction from the machine learning model to actual energy usage of the tool; and
determine a deviation between the actual energy usage and the predicted energy of the tool to maintain energy consumption efficiency of the tool.

15. The computer program product of claim 14, wherein the parameter is energy consumption of the tool and the model uses one or more independent relevant variables that relate to the energy consumption.

16. The computer program product of claim 14, wherein the operational states comprise at least one of: productive state (PRD); standby state (SBY); engineering state (ENG); scheduled downtown state (SDT); unscheduled down time state (UDT); and non-scheduled state (NST).

17. The computer program product of claim 14, wherein the machine learning is based on a regression analysis comprising a set of statistical methods used for estimation of relationships between a dependent variable and one or more independent variables of the tool.

18. The computer program product of claim 14, further comprising determining which independent variables of the tool comprises a strong correlation to energy consumption and using the determined independent variables for the modeling.

19. The computer program product of claim 14, wherein the comparing of the energy usage prediction from the machine learning model to the actual energy usage of the tool is over different operational states over a same duration of time.

20. A system comprising:
a processor, a computer readable memory, one or more computer readable storage media, and program instructions collectively stored on the one or more computer readable storage media, the program instructions executable to:
accumulate a parameter over a period of interest of a tool, the parameter comprising energy consumption of different operational states over a predetermined period of time;
model the parameter of the tool using machine learning to predict energy consumption of the tool over a selected subset of the different operational states;
compare the energy usage prediction from the machine learning model to actual energy usage of the tool; and
determine a deviation between the actual energy usage and the predicted energy of the tool and to increase energy consumption efficiency of the tool.
